(19) United States
(12) Patent Application Publication
(10) Pub. No.: US 2011/0061721 A1
(43) Pub. Date: Mar. 17, 2011

(54) LENS WITH INCREASING PITCHES

(75) Inventors: YU-SHU CHEN, Chu-Nan (TW); AN-CHI WEI, Chu-Nan (TW); CHIH-CHUNG TSAO, Chu-Nan (TW); SHAN-JU LIN, Chu-Nan (TW)

(73) Assignee: FOXSEMICON INTEGRATED TECHNOLOGY, INC., Chu-Nan (TW)

(21) Appl. No.: 12/835,744

(22) Filed: Jul. 14, 2010

(30) Foreign Application Priority Data
Sep. 15, 2009 (CN) 200910307046.7

(51) Int. Cl. H01L 31/02; G02B 3/08

(52) U.S. Cl. 136/252; 359/742

(57) ABSTRACT

A non-imaging lens includes a transparent member, a conical protrusion and a plurality of annular protrusions. The transparent member includes a first surface and a second surface. The first surface and the second surface are planar. The conical protrusion is defined on the first surface. The annular protrusions are concentrically defined on the first surface around the conical protrusion. Each of cross-sections of the annular protrusions approximately forms a right-angled triangle. The triangle includes a first angle, a second angle, a bottom surface, a first surface and a second surface. The first angle exceeds the second angle. The first angle is less than or equal to 90°. The bottom surfaces of the triangles increase in turn outwards from the conical protrusion.

### CROSS-REFERENCE TO RELATED APPLICATIONS

This application is related to patent application Ser. No. ______, entitled “LENS WITH A DETERMINED PITCH” and filed on ______, 2010 (Attorney Docket No. US26737) and patent application Ser. No. ______, entitled “LENS WITH MULTIPLE PROTRUSIONS” and field on ______, 2010 (Attorney Docket No. US26739). Such applications have the same inventors and assignee as the present application.

### BACKGROUND

1. Technical Field

The disclosure relates generally to lenses, and more particularly to a lens for condensing the solar light.

2. Description of the Related Art

Generally, solar light is considered to be aligned. A standard Fresnel lens is configured for concentrating solar light for a solar cell. However, the intensity of light through the Fresnel lens is not uniform. When the solar light passes through the Fresnel lens, the intensity of the center is normally higher than that of periphery. Thus, what is called for is a lens that can overcome the limitations described.

### BRIEF DESCRIPTION OF THE DRAWINGS

FIG. 1 is a top view of a non-imaging lens in accordance with a first embodiment of the disclosure.

FIG. 2 is a cross-section along line II-II of the non-imaging lens in FIG. 1.

FIG. 3 is a cross-section of the non-imaging lens in FIG. 1.

FIG. 4 is a cross-section of the non-imaging lens in FIG. 1 in a vertical orientation, showing an optical path of the non-imaging lens in FIG. 1.

FIG. 5 is a cross-section of a non-imaging lens in accordance with a second embodiment of the disclosure.

FIG. 6 is a cross-section of a non-imaging lens in accordance with a third embodiment of the disclosure.

FIG. 7 is a view similar to FIG. 4, showing a solar cell module utilizing the non-imaging lens in FIG. 1.

### DETAILED DESCRIPTION

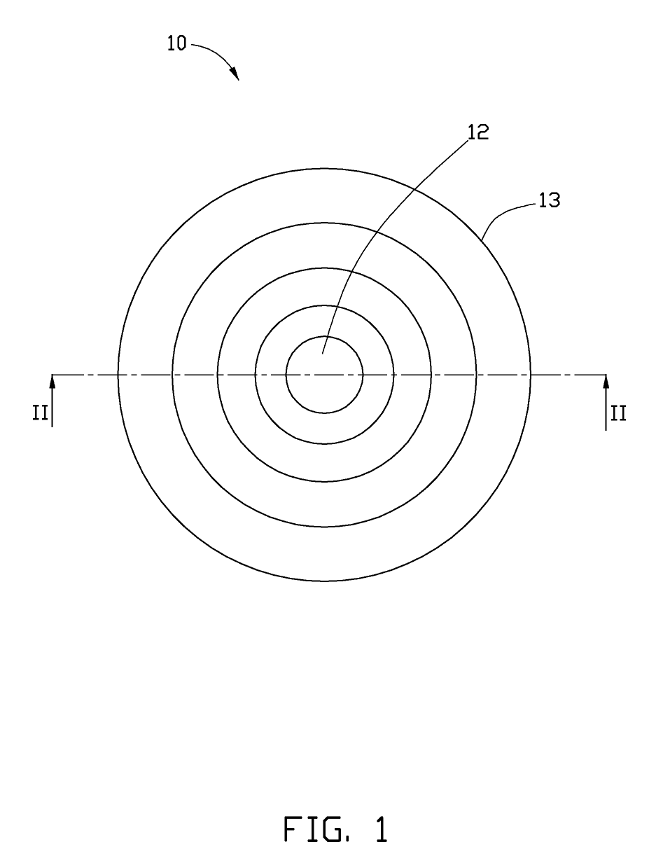

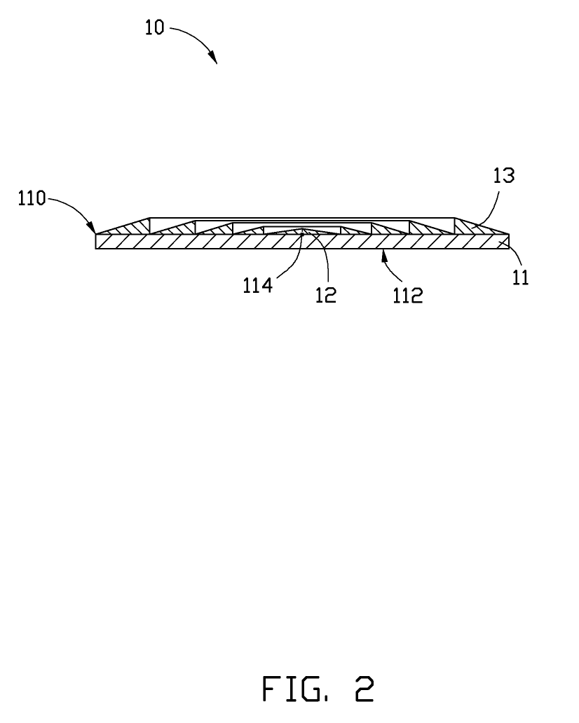

Referring to FIG. 1 and FIG. 2, a non-imaging lens 10 in accordance with a first embodiment of the disclosure includes a transparent member 11, a conical protrusion 12 and a plurality of annular protrusions 13.

The transparent member 11 is circular. The transparent member 11 includes a first surface 110 and a second surface 112. The second surface 112 is configured for receiving the solar light. The first surface 110 and the second surface 112 are planar. The transparent member 11 is made of resin or glass.

The conical protrusion 12 is defined at a center 114 of the first surface 110. The annular protrusions 13 are concentrically defined on the first surface 110 and configured around the conical protrusion 12. Each of cross-sections along the line II-II of the protrusions 13 approximately forms a right-angled triangle at a side of the center 114 of the first surface 110 of the transparent member 11. Each of the triangles includes a bottom surface 130, a first surface 132 which is perpendicular to the bottom surface 130, a second surface 134 which is slantwise to the bottom surface 130, a first angle θ and a second angle α and a third angle γ. The bottom surfaces 130 of the triangles are on the first surface 110. The second surfaces 132 are located toward the conical protrusion 12. The radius of the conical protrusion 12 and the widths of the bottom surfaces 130 increase in turn outwards from the center 114. The second angles α increase in turn outwards from the conical protrusion 12. In the first embodiment, a relation among the radius of the conical protrusion 12 and the widths of the bottom surfaces 130 outwards from the center 114 of the transparent member 11 provide an increasing arithmetical progression.

A cross section of the conical protrusion 12 could be considered as consisting of two right-angled triangles beside the center 114. A width of a bottom surface of each of the triangles defined by the conical protrusion 12 equals to the radius of the conical protrusion 12. The radius of the conical protrusion 12 is less than any of the widths of the bottom surfaces 130.

The transparent member 11 can be triangular or elliptical, there being no limitation to the shape as disclosed.

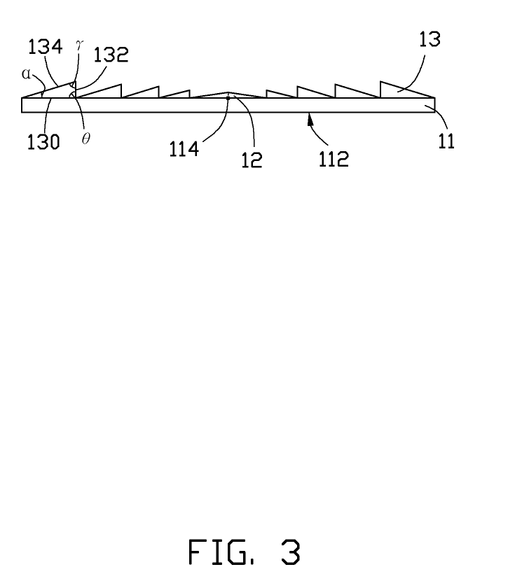

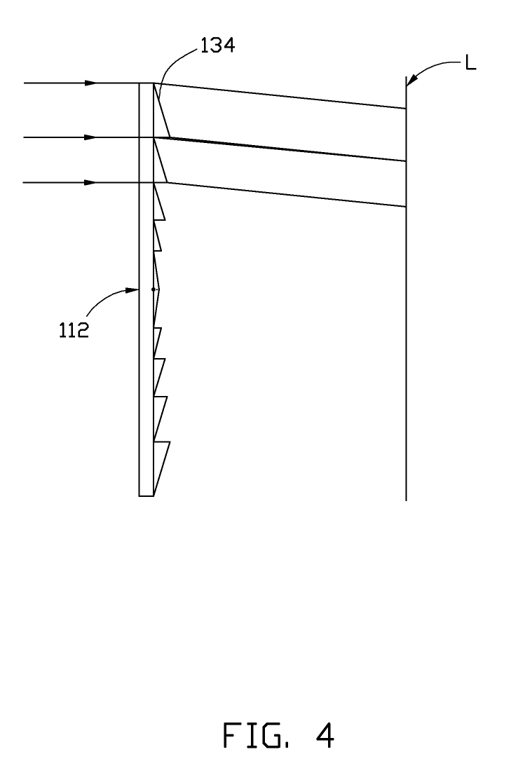

Referring to FIG. 3 and FIG. 4, the second surface 134 is configured for refracting the solar light. The widths of light spots corresponding to the annular protrusions 13 are in an increasing arithmetical progression along a radially outward direction. The intensities of the light spots are uniform.

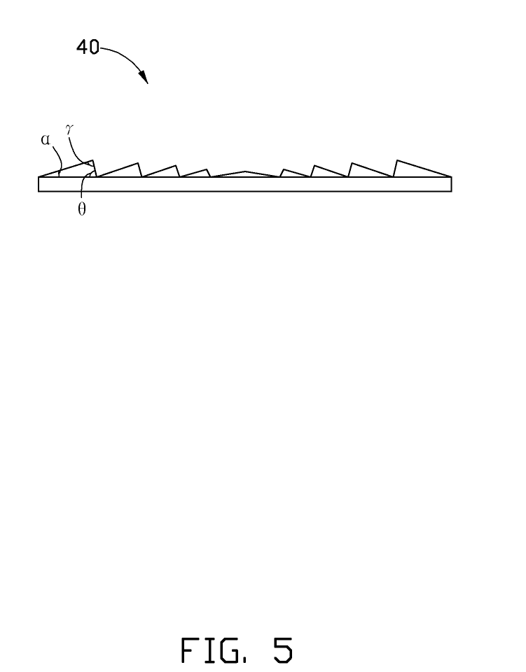

Referring to FIG. 5, a non-imaging lens 40 in accordance with a second embodiment of the disclosure is similar to the first embodiment, differing only in that the first angle θ is between 45° and 90° and the first angle θ exceeds the second angle α. For example, the first angle θ can be between 87° and 90°

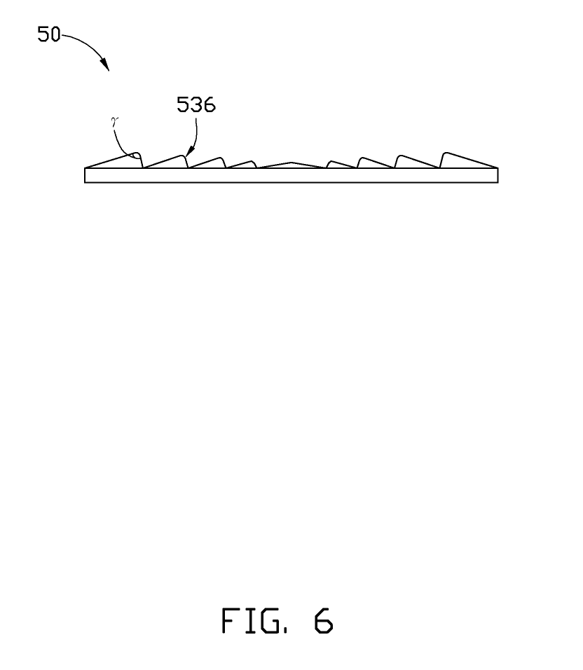

Referring to FIG. 6, a non-imaging lens 50 in accordance with a third embodiment of the disclosure is similar to the non-imaging lens 40 of the second embodiment, differing only in that a corner 536 of each of the triangles formed by the annular protrusions 13 in cross section corresponding to the third angle γ is a smooth corner.

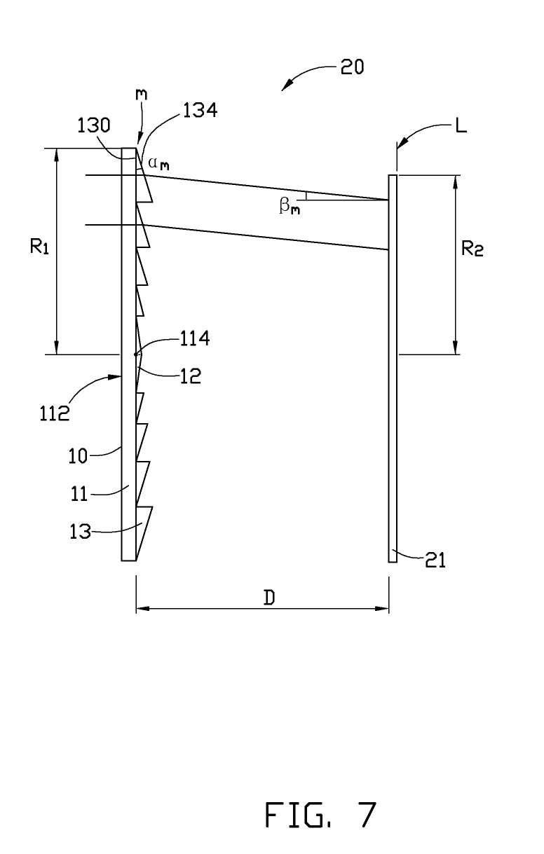

Referring to FIG. 7, a solar cell module 20 includes a solar cell plate 21 and a non-imaging lens 10 as shown in FIG. 1. The solar cell plate 21 is defined on L plane as shown in FIG. 4 towards the annular protrusions 13 of the lens 10 for efficiently receiving the solar light. The number of the annular protrusions 13, a radius of the transparent member 11 and a radius of the solar cell plate 21 can be determined according to specific requests. When the parameters of the solar device 20 satisfy formula (1) and formula (2), the uniform solar light is received by the solar cell plate 21.

$$\begin{matrix}{β}_{m} = {tan}^{- 1} \{ \frac{( {R}_{1} / {m}_{max} - {R}_{2} / {m}_{max} ) ( 2 m - 1 )}{2 D} \} & ( 1 ) \\ {α}_{m} = {tan}^{- 1} \{ \frac{sin {β}_{m}}{n - cos {β}_{m}} \} & ( 2 )\end{matrix}$$

R₁ is the radius of the transparent member 11. R₂ is the radius of the solar cell plate 21. D is a distance between the solar cell plate 21 and the first surface 110 of the transparent member 11. mₘₐₓ is total number of the triangles at a side of the transparent member 11 relative to the center 114, which in the embodiment of FIG. 7 is seven (7). The conical protrusion 12 forms two triangles besides the center 114. Either of the triangles defined by the conical protrusion 12 is considered as the first triangle. Either of the triangles defined by the outermost annular protrusion 13 is considered as the last triangle. αₘ is the second angle of the m^{th} triangle. βₘ is an incident angle relative to the solar light plate 21 of the light through the m^{th} triangle. n is a refractive coefficient of the non-imaging lens 10.

Uniform intensity can be easily obtained utilizing the non-imaging lens 10 satisfying the formulae (1) and (2).

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A non-imaging lens comprising:
a transparent member comprising a first surface and a second surface, the first surface and the second surface configured to be planar;
a conical protrusion; and
a plurality of annular protrusions, the conical protrusion defined on the first surface of the transparent member, the annular protrusions concentrically defined around the conical protrusion, each of cross-sections of the annular protrusions at a side of a center of the transparent member forming a triangle, the triangle comprising a first angle, a second angle, a bottom surface, a first surface and a second surface, the first angle defined by the bottom surface and the first surface, the second angle defined by the bottom surface and the second surface, the first angle exceeding the second angle, the first angle configured to be less than or equal to 90°, widths of the bottom surfaces of the triangles configured to increase in turn outwards from the conical protrusion.

2. The lens as claimed in claim 1, wherein the widths of the bottom surfaces of the triangles provide an increasing arithmetic progression.

3. The lens as claimed in claim 1, wherein the first angles of the triangles are uniform.

4. The lens as claimed in claim 1, wherein the first angle is between 45° and 90°.

5. The lens as claimed in claim 4, wherein the first angle is between 87° and 90°.

6. The lens as claimed in claim 5, wherein the first angle is 90°.

7. The lens as claimed in claim 1, wherein the second angles of the triangles increase in turn outwards from the conical protrusion.

8. The lens as claimed in claim 1, wherein each of the triangles further comprises a third angle and a smooth corner corresponding to the third angle.

9. The lens as claimed in claim 1, wherein the transparent member is circular.

10. The lens as claimed in claim 1, wherein the transparent member is rectangular.

11. A solar cell module comprising:
a non-imaging lens comprising:
a transparent member comprising a first surface and a second surface, the first surface and the second surface configured to be planar;
a conical protrusion; and
a plurality of annular protrusions, the conical protrusion defined on the first surface of the transparent member, the annular protrusions concentrically defined around the conical protrusion, each of cross-sections of the annular protrusions at a side of a center of the transparent member forming a triangle, the triangle comprising a first angle, a second angle, a bottom surface, a first surface and a second surface, the first angle defined by the bottom surface and the first surface, the second angle defined by the bottom surface and the second surface, the first angle exceeding the second angle, the first angle configured to be less than or equal to 90°, widths of the bottom surfaces of the triangles configured to increase in turn outwards from the conical protrusion; and
a circular solar cell plate, the solar cell plate defined parallel to the lens and configured towards the protrusions of the lens, the solar cell module satisfying following formulae:
$${β}_{m} = {tan}^{- 1} \{ \frac{( {R}_{1} / {m}_{max} - {R}_{2} / {m}_{max} ) ( 2 m - 1 )}{2 D} \} , \\ {α}_{m} = {tan}^{- 1} \{ \frac{sin {β}_{m}}{n - cos {β}_{m}} \} ,$$
wherein R₁ is a radius of the transparent member, R₂ is a radius of the solar cell plate, D is a distance between the solar cell plate and a first surface of the lens, mₘₐₓ is total number of the triangles formed by the annular protrusions and an additional triangle formed by a cross section of the conical protrusion at the side of the center of the transparent member, the additional triangle is considered as the first triangle while the triangle formed by an outmost annular protrusion is considered as the last triangle, αₘ is the second angle of the m^{th} triangle, βₘ is an incident angle relative to the solar cell plate of the light through the m^{th} triangle, and n is a refractive coefficient of the lens.

12. The solar cell module as claim 11, wherein the first angles of the triangles are uniform.

13. The solar cell module as claim 12, wherein the first angles of the triangles each are 90°.

14. The solar cell module as claim 11, wherein each of the triangles further comprises a third angle and a smooth corner corresponding to the third angle.

15. The solar cell module as claim 11, wherein the widths of the bottom surfaces increase in turn, the widths of the bottom surfaces configured to provide an arithmetic progression.
